(19) United States
(12) Patent Application Publication
(10) Pub. No.: US 2023/0067857 A1
(43) Pub. Date: Mar. 2, 2023

(54) ENCLOSED CONDENSING PACKAGE FOR ELECTRONIC RACKS

(71) Applicant: Baidu USA LLC, Sunnyvale, CA (US)

(72) Inventor: TIANYI GAO, Sunnyvale, CA (US)

(21) Appl. No.: 17/465,060

(22) Filed: Sep. 2, 2021

(51) Int. Cl. H05K 7/20

(52) U.S. Cl. CPC H05K 7/20827; G01F 23/00

(57) ABSTRACT

A condensing unit includes a vapor container housing condensing coils, the vapor container being pressurized to increase a rate of condensation of two phase coolant in vapor phase. The condensing unit includes a vapor inlet for vapor to enter the vapor container. The condensing unit includes a liquid container underneath the vapor container and attachable to the vapor container to receive two phase liquid coolant from the vapor container. The condensing unit includes a liquid level sensor within the liquid container to measure a liquid level. The condensing unit includes a pressure sensor at the vapor container to measure a pressure within the vapor container, where the pressure sensor is used to regulate a pressure in the condensing unit within a predetermined range thereby maintaining a steady rate of condensation by the condensing coils and an outflow rate of two phase liquid coolant from the liquid container.

### FIELD OF THE INVENTION

Embodiments of the present invention relate generally to server and data center cooling. More particularly, embodiments of the invention relate to an enclosed condensing package for electronic racks.

### BACKGROUND

Thermal management for a data center that includes several active electronic racks is critical to ensure proper performance of servers and other information technology (IT) equipment (e.g., performing IT services) that is operating in the racks. Without proper thermal management, however, the thermal environment (e.g., temperature) within the racks may exceed thermal operational thresholds, which may result in adverse consequences (e.g., servers failing, etc.). One way to manage the thermal environment is the use of cooling air to cool the IT equipment. The cooling air is recirculated through cooling units. Heat generated by the IT equipment is captured by the cooling air and is extracted by the cooling unit. One common cooling unit is a computer room air conditioning (CRAC) unit that is a device that intakes hot exhaust return air and supplies cooling air to maintain a data center's thermal environment. With higher and higher power densities, designing the thermal management solution becoming more challenge. One effective way is to move the cooling liquid closer to the heat load, such as the electronics. With such method, not only the high power density can be managed, but also the cooling air requirement may significantly decreased.

Recently, data centers have been deploying high-power density electronic racks, where a large quantity of high-density chips are packaged closer together to provide more computing power. Cooling these high-density racks by maintaining a proper thermal environment may be an issue with existing cooling systems, such as a CRAC unit. For instance, although the CRAC unit may maintain the thermal environment with more conventional (or lower-density) racks, the unit may be unable to effectively cool high-power density racks because they may generate heat load at a higher rate due to the higher density electronics. Or significant cost may be needed for upgrading a CRAC system to satisfy a cooling requirement of a high density deployment. Another challenge for air cooling high density racks is moving a large amount of airflow sufficient to cool the racks. Since heat removal capacity of fluid is much larger than heat removal capacity of air, thus it is more economical to move cooling fluid for cooling. Therefore, designing the cooling fluid closer to the IT, indirectly or directly in contact with electronics are an effective mean.

Immersion cooling, on the other hand, which involves at least partially submerging electronics in a non-conductive dielectric solution is a feasible solution for high-density electronics. Implementing immersion cooling in existing data centers, however, has challenges. For example, a data center's cooling infrastructure may need to be modified to be able to operate in an immersion cooling system, since existing data centers are designed for either air cooling or other types of liquid cooling. Also, immersion cooling is a more complex cooling solution than existing air/liquid solutions. For instance, single-phase immersion cooling requires complex hardware design for electronic components, mechanical pumps that may fail/leak, and significant room modification for deployment in a data center. As another example, conventional two phase immersion cooling systems include a condenser that is packaged within an immersion tank along with the submerged electronics (e.g., positioned above the electronics). When maintenance is performed (e.g., when a server needs to be replaced), a data center onsite operator must remove the condenser from the tank, thereby breaking the existing cooling loop which may lead to a loss of dielectric solution. In addition, in order to prevent overheating while performing maintenance, the electronics within the tank may be shut down, which results in service interruption. Immersion cooling can be understood as designing the thermal management with cooling fluid in direct contact with the electronics.

Existing solutions for the condenser of immersion cooling typically includes condensing coils which condense two phase coolant from vapor to liquid phase and return the liquid directly to electronic racks. Such solutions may lack resilience and is difficult to manage the liquid.

### BRIEF DESCRIPTION OF THE DRAWINGS

Embodiments of the invention are illustrated by way of example and not limitation in the figures of the accompanying drawings in which like references indicate similar elements.

FIG. 1 is a block diagram illustrating a condensing package according to one embodiment.

FIG. 2 is a block diagram illustrating a condensing package with a different internal packaging design according to one embodiment.

FIG. 3 is a block diagram illustrating a condensing package with an alternate release port according to one embodiment.

FIG. 4 is a block diagram illustrating an airtight condensing package according to one embodiment.

FIG. 5 is a block diagram illustrating a condensing package with a single liquid outlet port according to one embodiment.

FIGS. 6A-6B illustrate a front view and a side view, respectively, of an electronic rack 600 according to one embodiment.

FIG. 7 is a flow diagram to self-regulate two phase coolant in a condensing package according to one embodiment.

### DETAILED DESCRIPTION

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

The current solution proposes a condensing package having an optimal environment for controllable vapor condensation, and at a same time, enabling two phase coolant fluid flow to the load.

According to a first aspect, a condensing unit of an electronic rack includes a vapor container housing condensing coils, the vapor container being pressurized to increase a rate of condensation of two phase coolant in vapor phase. The condensing unit includes a vapor inlet situated at the vapor container for two phase liquid coolant in vapor phase to enter the vapor container. The condensing unit includes a liquid container situated underneath the vapor container and attachable to the vapor container to receive two phase liquid coolant in liquid phase from the vapor container. The condensing unit includes a liquid level sensor situated within the liquid container to measure a liquid level for liquid contained in the liquid container. The condensing unit includes a pressure sensor situated at the vapor container to measure a pressure within the vapor container, where the pressure sensor is used to regulate a pressure in the condensing unit within a predetermined range thereby maintaining a steady rate of condensation by the condensing coils and an outflow rate of two phase liquid coolant from the liquid container.

In one embodiment, the vapor inlet is coupled to a line that extends to a server region of the electronic rack, where the server region includes a number of server slots to receive a number of servers, where each of the servers is at least partially submerged within two phase liquid coolant within the immersion section, where, when the servers operate, the servers generate heat that is transferred to the two phase liquid coolant thereby causing at least some of the two phase liquid coolant to turn into a vapor.

In one embodiment, the vapor container includes a release port situated near a top portion of the vapor container and a release valve coupled to the release port, where the release valve is activatable by the pressure sensor to release vapor and/or air from the vapor container.

In one embodiment, the release valve is a three way valve having a first port to release air to a surrounding environment and a second port coupled to another condensing unit.

In one embodiment, the vapor container further includes a cooling liquid supply line and a cooling liquid return line, where the cooling liquid supply line and cooling liquid return line are coupled to the condensing coils to supply cooling liquid from, and return cooling liquid to a facility source.

In one embodiment, the cooling liquid supply line includes a supply pump, where the supply pump is controlled at a variable rate by the pressure sensor to increase or decrease a rate of condensation of two phase liquid coolant in vapor phase, to maintain the pressure within the vapor container to the predetermined range.

In one embodiment, the liquid container further includes a direct return line operable without a pump to return two phase liquid coolant in liquid phase to a server region of the electronic rack caused by the pressure built up within the vapor container.

In one embodiment, the liquid container further includes a liquid outlet line and a return pump, where the return pump is activatable by the pressure sensor to return two phase liquid coolant in liquid phase to a server region of the electronic rack or to a facility liquid coolant source.

In one embodiment, the vapor container includes a release port situated at a section of the vapor inlet and a release valve coupled to the release port, where the release valve is activatable by the pressure sensor to release vapor and/or air from the vapor container via the vapor inlet.

In one embodiment, the vapor container and liquid container are separated by an air sealing mechanism to lock in an air volume within the vapor container.

In one embodiment, the air sealing mechanism allows liquid to flow between the vapor container and the liquid container but prevents vapor from flowing from the vapor container to the liquid container.

In one embodiment, the condensing unit further includes an external chassis containing the vapor container and the liquid container.

According to a second aspect, an electronic rack includes a server region of the electronic rack. The server region includes a number of server slots to receive a number of servers, where each of the servers is at least partially submerged within two phase liquid coolant within the immersion section, where, when the servers operate, the servers generate heat that is transferred to the two phase liquid coolant thereby causing at least some of the two phase liquid coolant to turn into a vapor. The electronic rack includes a condensing unit of an electronic rack coupled to the server region, the condensing unit includes a vapor container housing condensing coils, the vapor container being pressurized to increase a rate of condensation of two phase coolant in vapor phase. The condensing unit includes a vapor inlet situated at the vapor container for two phase liquid coolant in vapor phase to enter the vapor container. The condensing unit includes a liquid container situated underneath the vapor container and attachable to the vapor container to receive two phase liquid coolant in liquid phase from the vapor container. The condensing unit includes a liquid level sensor situated within the liquid container to measure a liquid level for liquid contained in the liquid container. The condensing unit includes a pressure sensor situated at the vapor container to measure a pressure within the vapor container, wherein the pressure sensor is used to regulate a pressure in the condensing unit within a predetermined range thereby maintaining a steady rate of condensation by the condensing coils and an outflow rate of two phase liquid coolant from the liquid container.

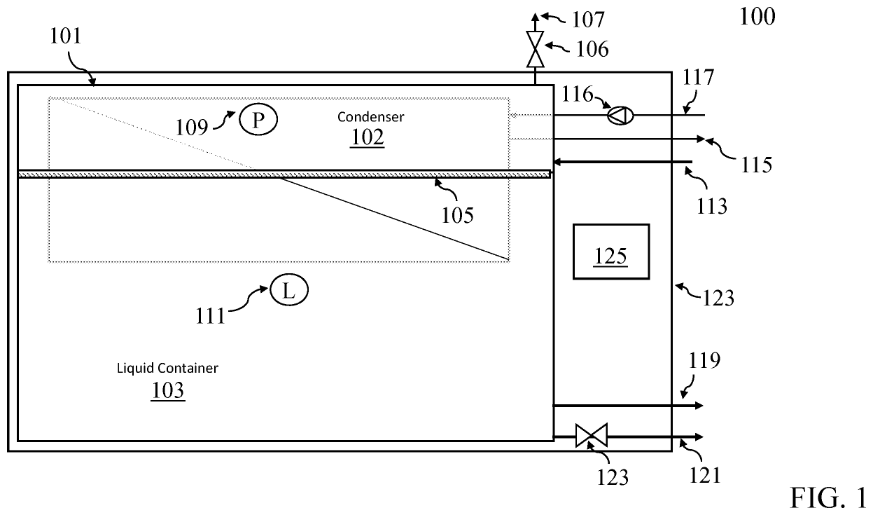

FIG. 1 is a block diagram illustrating a condensing package 100 according to one embodiment. Condensing package/unit 100 can be a standalone package or a package integrated with an electronic rack. Condensing package 100 can remove heat from a fluid (e.g., two phase coolant) via condensing coils 102 that can undergo air-to-liquid heat exchange or liquid-to-liquid heat exchange. For the purpose of disclosure, this specification describes liquid-to-liquid heat exchange, but air-to liquid heat exchange can be applied in addition to or instead of the liquid-to-liquid heat exchange.

According to one embodiment, condensing package 100 includes vapor region (e.g., vapor container) 101 and liquid container 103, where condensing coils 102 are contained within vapor region 101. Note that liquid container 103 can be partially filled with liquid, and condensing coil 102 can be situated above the liquid surface. In one embodiment, vapor region 101 is separated from liquid container 103 via a sealing layer 105. In one embodiment, sealing layer 105 seals vapor in vapor region 101 but allows liquid to flow between vapor region 101 and liquid container 103. In one embodiment, the pressure at vapor region 101 is same as the pressure at liquid container 103 or the pressurized volume within vapor region 101 is higher than pressure at liquid container 103.

In one embodiment, vapor region 101 includes a one-way air release mechanism that allows liquid to flow between the vapor region 101 and liquid container 103 but prevents vapor from flowing from vapor region 101 to liquid container 103. In one embodiment, the one-way air release mechanism is the sealing layer 105 between vapor region 101 and liquid container 103. In one embodiment, one-way air release mechanism can be a s-shaped through access, that can trap vapor in the vapor region 101. Condensing package 100 can include an external package 123, which contains vapor region 101 and liquid container 103. In addition, sealing layer 105 can prevent air from entering into vapor region 101 when the vapor pressure decreased.

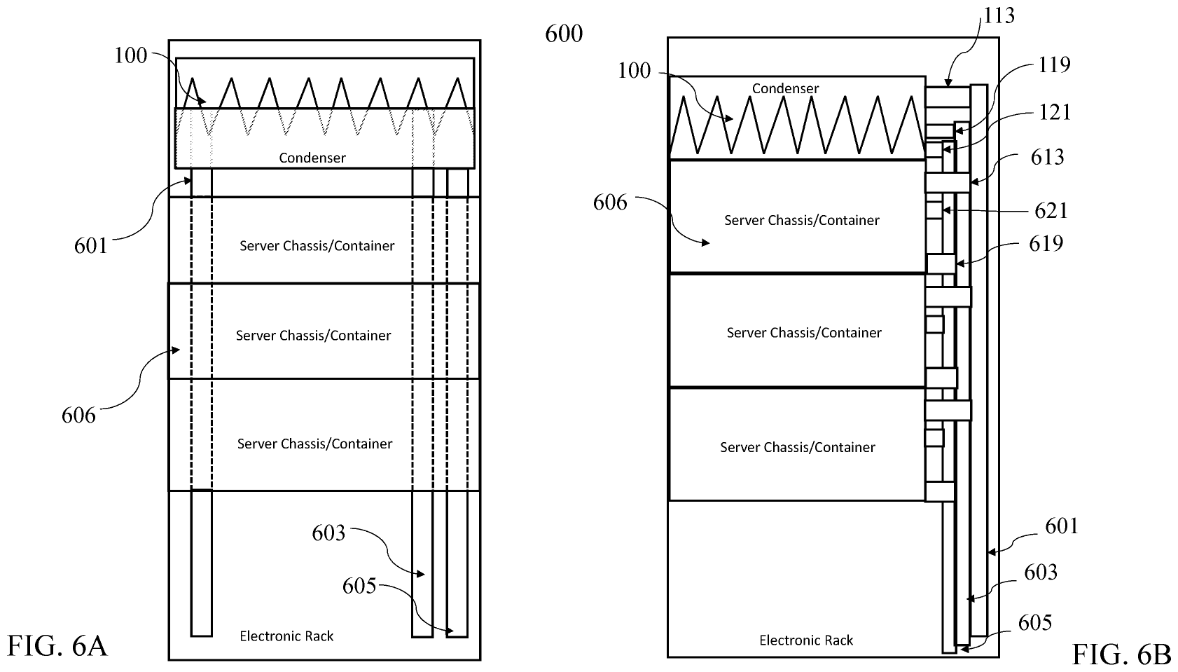

In one embodiment, vapor region 101 includes pressure sensor 109 to measure vapor pressure within vapor region 101. In one embodiment, vapor region 101 includes vapor inlet 113 for receiving a vapor. The vapor can be two-phase coolant in vapor phase, where the two-phase coolant is used in an immersion system to removes heat from IT electronics, as further described in FIGS. 6A-6B.

In one embodiment, vapor region 101 is assembled with cooling liquid supply 117 and cooling liquid return 115. Cooling liquid supply 117 and cooling liquid return 115 are used to recirculate a cooling fluid (such as water or antifreeze) to condensing coils 102 contained within vapor region 101. In one embodiment, vapor region 101 includes a vapor releasing port 107 mounted on a top portion of package 123. In one embodiment, air released from vapor releasing port 107 exits to surrounding atmosphere, outside of data center facility. In one embodiment, when in operation, vapor releasing port 107 can be coupled to a vapor releasing port of another condensing package, for a closed system (e.g., vapor is contained and can travel between one or more condensing packages/units). A valve 106 of vapor releasing port 107 can be opened to release air that can be initially trapped within vapor region 101 or liquid container 103 when condensing package 100 initially starts processing a vapor (system initialization).

In one embodiment, a pressure measurement from pressure sensor 109 can be used to control a rate of cooling fluid flow rate at condensing coils 102, thus controlling a vapor condensation rate within vapor region 102. For example, given a constant vapor inflow, at vapor inlet 113, a feedback controller 125 can self-regulate a pressure measurement of pressure sensor 109 to be within a predetermined range. In one embodiment, feedback controller 125 can be a dedicated unit for condensing package 100 or be part of an electronic rack. The predetermined range can be several Bars above an atmospheric pressure. The higher pressure can provide enhanced condensation performance (assist vapor condensation at condensing coils 102) and at the same time, because a pressure is loaded on the surface of liquid, the higher pressure can assist liquid flow via direct return port 119.

When pressure measurement falls below the predetermined range, controller can decrease the recirculating cooling liquid flow rate at supply/return 115/117, via pump 116. Until pressure builds up and the pressure measurement of pressure sensor 109 is above the predetermined range, controller can then increase the recirculating cooling liquid flow rate at supply/return 115/117.

In one embodiment, the pressure measurement can regulate a rate of two-phase coolant liquid outflow for liquid contained within liquid container 103. For example, when pressure measurement of pressure sensor 109 is above the predetermined range, controller opens a proportionally valve 123 of outlet 121, to increase a liquid outflow until the pressure falls within the predetermined range, in turn decreasing the pressure within vapor region 101/liquid container 103. When two phase coolant liquid stored in liquid container 103 is at a low, pressure decreases, thus decreasing the amount of condensed liquid returning to the load.

In one embodiment, a pressure measurement from pressure sensor 109 can be used to control a valve of vapor releasing port 107. For example, when pressure measurement is greater than the predetermined range, feedback controller 125 can open a proportional valve of vapor releasing port 107 until the pressure falls within the predetermined range. In sum, a reading of pressure sensor can be used to control a cooling liquid pump 116 at cooling liquid supply 117, valve 106 at vapor release port 107, and valve 123 at liquid return 121. Thus, pressure sensor 109 can be used to regulate a flow rate of two-phase coolant, including coolant condensation and coolant outflow. In one embodiment, vapor release port 107 can be connected with an auxiliary condensing unit. In one embodiment, valve 106 is a three way valve controlled by the pressure of vapor region 101, and the three way valve includes one port to release air to a surrounding environment and one port coupled to an auxiliary condensing unit (e.g., another condensing package) to release/take in vapor from the auxiliary condensing unit.

In one embodiment, liquid container 103 includes liquid level sensor 111. Liquid level sensor 111 can measure a liquid level of two-phase coolant in liquid phase stored within liquid container 103. Liquid container 103 can contain two liquid return ports 119-121, a direct return port 119 and a liquid outlet port 121. Both ports 119-121 can be used to direct a condensed liquid to load (e.g., electronic rack).

In one embodiment, liquid outlet port 121 can direct condensed liquid to a facility two phase coolant source. In one embodiment, a measurement at liquid level sensor 111 can be used to control valve 123 for liquid outlet 121. For example, if liquid level sensor 111 provides a reading that the liquid is above a first threshold, a feedback controller 125 can open valve 123, assisting liquid outflow, until reading the liquid returns below a second threshold.

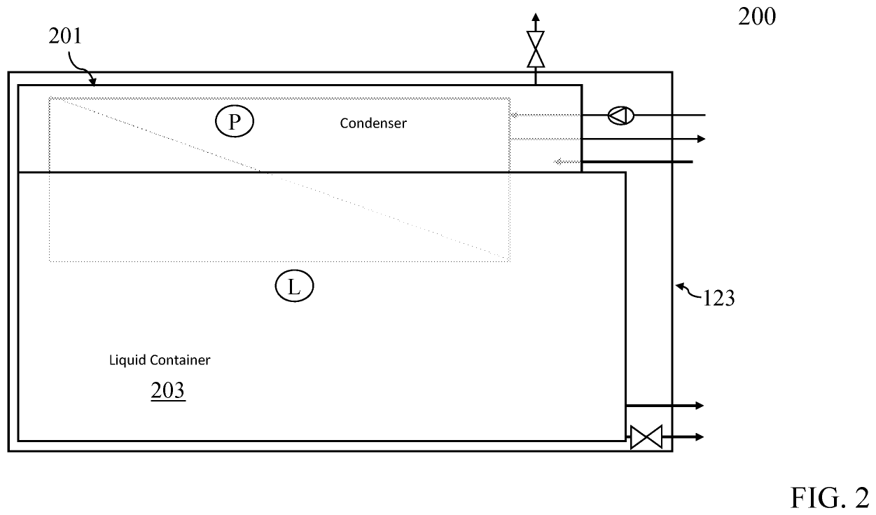

FIG. 2 is a block diagram illustrating a condensing package 200 with a different internal packaging according to one embodiment. The entire external chassis can be considered as the vapor containment region. Condensing package 200 can represent condensing package 100 of FIG. 1. For example, vapor region 201 and liquid container 203 have form factors larger in a height, width, or length dimensions than vapor region 101 and liquid container 103 of FIG. 1, respectively. Since vapor region 201 and liquid container 203 are contained within package 123, dimensions of vapor region 201 and liquid container 203 in combination can be any size to form a sealed environment within package 123.

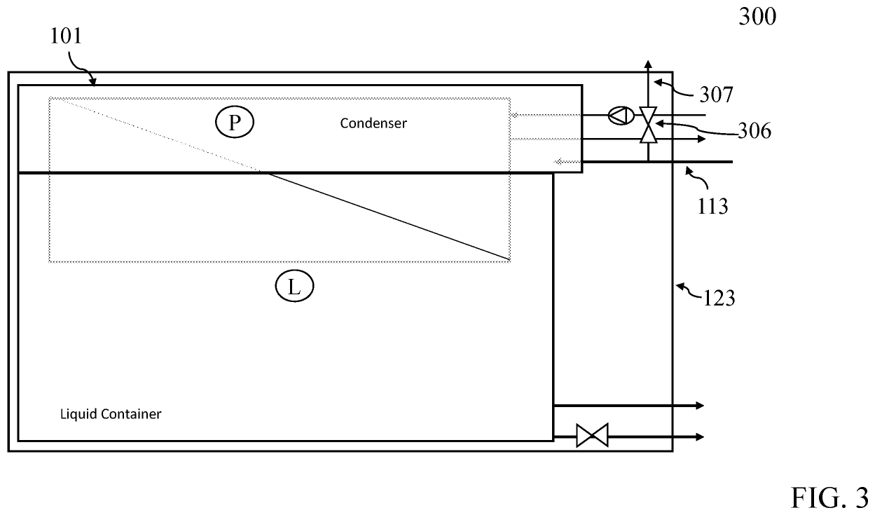

FIG. 3 is a block diagram illustrating a condensing package 300 with an alternate release port 307 according to one embodiment. Condensing package 300 can represent condensing package 100 of FIG. 1. Condensing package 300 can include vapor release port 307 and associated valve 306, where vapor release port 307 is located on vapor inlet 113, at a region between condensing package 123 and vapor region 101. In this case, vapor release port 307 is designed and implemented as part of package 123.

As described with respect to FIG. 1, vapor release port 307 and valve 306 can be used to release vapor pressure from vapor region 101. In one embodiment, vapor release port 307 can be coupled to vapor release ports (not shown) of other condensing packages. In another embodiment, vapor release port 307 is routed to the atmosphere, outside of a data center facility, so that vapor can be released to the atmosphere. In one embodiment, vapor release port 307 is an extension port to an auxiliary condensing unit.

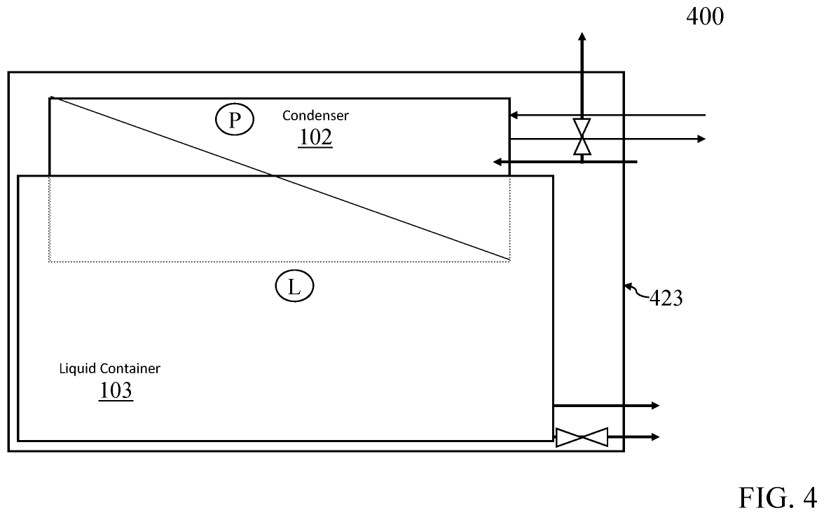

FIG. 4 is a block diagram illustrating an airtight condensing package 400 according to one embodiment. Condensing package 400 can represent condensing package 100 of FIG. 1. In this design, condensing package 423 is an airtight region containing condensing coil 102 and liquid container 103. Condensing package 423 is without a vapor region, but the functionality of the vapor region is provided by condensing package 423.

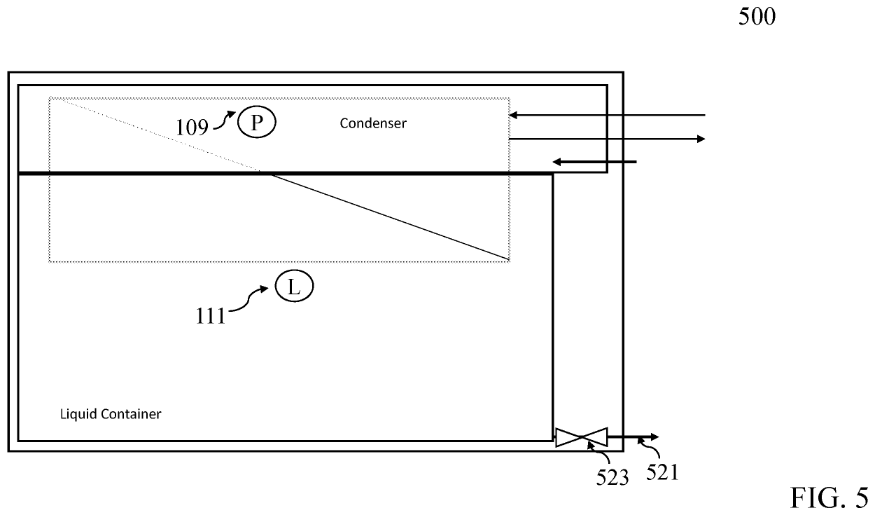

FIG. 5 is a block diagram illustrating a condensing package 500 with a single liquid outlet port according to one embodiment. Condensing package 500 can represent condensing package 100 of FIG. 1. In one embodiment, condensing package 500 includes only liquid outlet port 521 and associated valve 523 for liquid release, where valve 523 is controllable by pressure sensor 109 and/or liquid level sensor 111 via a feedback controller (not shown). The controlling of the valve 523 can impact a fluid volume flow rate of outlet 521. In this embodiment, valve 523 has control of the liquid outflow, without a direct return which is a constant open valve without any outflow control. The valve can be set as fully open or partially open in an embodiment.

FIGS. 6A-6B illustrate a front view and a side view, respectively, of an electronic rack 600 according to one embodiment. FIG. 6 shows a corresponding rack level design for condensing package 100. In one embodiment, electronic rack 600 can include one or more manifold/distribution lines 601-605 to distribute coolant between one or more servers 606 and condensing package 100. For example, rack 600 can include vapor manifold 601. Vapor manifold 601 can be coupled between vapor inlet 103 of package 100 and vapor connectors 613 of servers.

Rack 600 can include liquid supply manifold 603. Liquid supply manifold 603 can be coupled between direct liquid outlet 119 of condensing package 100 and liquid supply connectors 619 of one or more servers 606 populated at rack 600. Liquid supply manifold 603 can distribute condensed two-phase coolant in liquid phase from condensing package 100 to the one or more servers 606.

Rack 600 can include liquid releasing manifold 605. Liquid releasing manifold 605 can be coupled between liquid outlet 121 of condensing package 100 and liquid outlet connectors 621 of one or more servers 606 populated at rack 600. In one embodiment, liquid outlet connectors 621 is connected to a facility source (not shown). Liquid releasing manifold 605 can release the coolant from condensing package 100 and/or one or more servers 606 to the facility source. In one embodiment, liquid releasing manifold 605 can supply a coolant from the facility source to one or more servers 606 populated on electronic racks. The server/condensing package liquid connectors can be either blind mating connectors or female/male mating connectors.

In one embodiment, servers 606 can be configured to provide IT services. Specifically, servers 606 may include a host server (referred to as a host node) and/or one or more compute servers (also referred to as computing nodes, such as CPU server and GPU server). The host server (having one or more CPUs) typically interfaces with clients over a network (e.g., Internet) to receive a request for a particular service such as storage services (e.g., cloud-based storage services such as backup and/or restoration), executing an application to perform certain operations (e.g., image processing, deep data learning algorithms or modeling, etc., as a part of a software-as-a-service or SaaS platform). In response to the request, the host server distributes the tasks to one or more of the performance computing nodes or compute servers (having one or more GPUs) managed by the host server. In one embodiment, servers 606 can perform any type of computing task and/or can be any type of computing device (e.g., a server, a storage device, etc.). In one embodiment, servers 606 can be edge computing devices. Thus, while servers 606 provide the IT services, each of servers 606 generates heat that is transferred to two phase coolant.

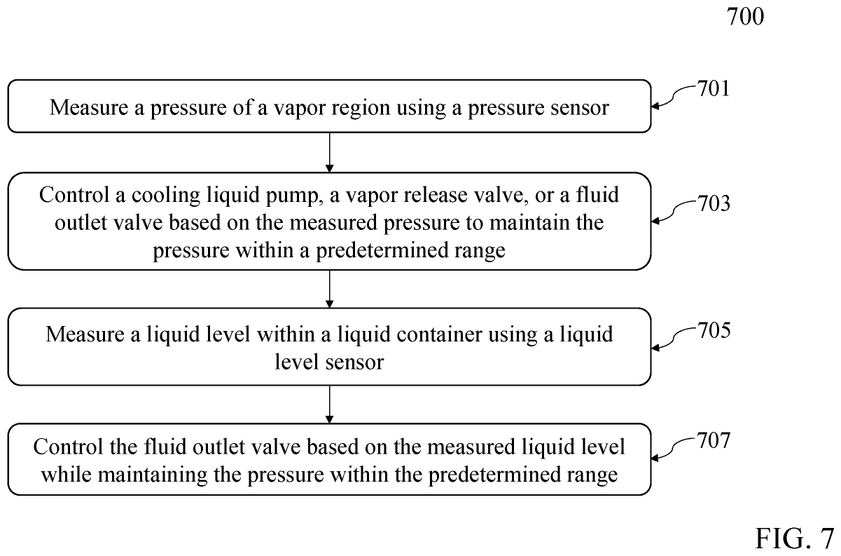

FIG. 7 is a flow diagram to self-regulate two phase coolant in a condensing package according to one embodiment. Flow diagram 700 may be performed by processing logic which may include software, hardware, or a combination thereof. In one embodiment, flow chart is performed by feedback controller 125 of FIG. 1.

At operation 701, processing logic measures a pressure of a vapor region using a pressure sensor 109. In one embodiment, the vapor region can be an air sealed vapor region 101 as shown in FIG. 1. In one embodiment, the vapor region is an air sealed environment of package 423, as shown in FIG. 4.

At operation 703, processing logic controls a cooling liquid pump, a vapor release valve, and/or a fluid outlet valve based on the measured pressure to maintain the pressure within a predetermined range.

For example, when the pressure is above the predetermined range, processing logic can increase a flow rate at cooling liquid pump 116, thereby increasing a condensation rate of two phase coolant from a vapor phase to a liquid phase, and/or processing logic can open vapor release valve 106 so vapor can escape from port 107, and/or processing logic can open valve 123 so coolant liquid can be released to servers/facility via outlet 121. When the pressure is below the predetermined range, processing logic can decrease a flow rate at cooling liquid pump 116, thereby decreasing a condensation rate of two phase coolant from a vapor phase to a liquid phase, or processing logic can close vapor release valve 106 so vapor is contained in vapor region, or processing logic can close valve 123 so coolant liquid can be contained within a liquid container 103.

The feedback controller may perform the operations in a combination manner or in any ordering. Here, an optimized vapor pressure not only ensures proper condensation, but also enable efficient using of cooling fluid, assisting two phase liquid flow returning to the electronic rack, and so on.

At operation 705, processing logic measures a liquid level within a liquid container 103 using a liquid level sensor 111.

At operation 707, processing logic controls the fluid outlet valve based on the measured liquid level while maintaining the pressure within the predetermined range.

For example, if the liquid level is above a first threshold, processing logic can open valve 123 so coolant liquid can be released to servers/facility via outlet 121. If liquid level is below a second threshold, processing logic can close valve 123 so coolant liquid can be contained within a liquid container 103. Based on the liquid outflow, processing logic can sense the pressure at a next cycle, and controls the cooling liquid pump, vapor release valve, and/or fluid outlet valve based on the measured pressure.

Thus, the pressure sensor and liquid level sensor are used to manage the container environment for vapor condensation, cooling liquid supply, and/or the coolant outflow control.

Note that some or all of the components as shown and described above may be implemented in software, hardware, or a combination thereof. For example, such components can be implemented as software installed and stored in a persistent storage device, which can be loaded and executed in a memory by a processor (not shown) to carry out the processes or operations described throughout this application. Alternatively, such components can be implemented as executable code programmed or embedded into dedicated hardware such as an integrated circuit (e.g., an application specific IC or ASIC), a digital signal processor (DSP), or a field programmable gate array (FPGA), which can be accessed via a corresponding driver and/or operating system from an application. Furthermore, such components can be implemented as specific hardware logic in a processor or processor core as part of an instruction set accessible by a software component via one or more specific instructions.

In the foregoing specification, embodiments of the invention have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. A condensing unit of an electronic rack, comprising:
a vapor container housing condensing coils, the vapor container being pressurized to increase a rate of condensation of two phase coolant in vapor phase;
a vapor inlet situated at the vapor container for two phase liquid coolant in vapor phase to enter the vapor container;
a liquid container situated underneath the vapor container and attachable to the vapor container to receive two phase liquid coolant in liquid phase from the vapor container;
a liquid level sensor situated within the liquid container to measure a liquid level for liquid contained in the liquid container; and
a pressure sensor situated at the vapor container to measure a pressure within the vapor container, wherein the pressure sensor is used to regulate a pressure in the condensing unit within a predetermined range thereby maintaining a steady rate of condensation by the condensing coils and an outflow rate of two phase liquid coolant from the liquid container.

2. The condensing unit of claim 1, wherein the vapor inlet is coupled to a line that extends to a server region of the electronic rack, wherein the server region comprises a plurality of server slots to receive a plurality of servers, wherein each of the servers is at least partially submerged within two phase liquid coolant within an immersion section, wherein, when the servers operate, the servers generate heat that is transferred to the two phase liquid coolant thereby causing at least some of the two phase liquid coolant to turn into a vapor.

3. The condensing unit of claim 1, wherein the vapor container comprises:
a release port situated near a top portion of the vapor container; and
a release valve coupled to the release port, wherein the release valve is activatable by the pressure sensor to release air and/or vapor from the vapor container.

4. The condensing unit of claim 3, wherein the release valve is a three way valve having a first port to release air to a surrounding environment and a second port coupled to another condensing unit.

5. The condensing unit of claim 1, wherein the vapor container further comprise:
a cooling liquid supply line; and
a cooling liquid return line, wherein the cooling liquid supply line and cooling liquid return line are coupled to the condensing coils to supply cooling liquid from, and return cooling liquid to a facility source.

6. The condensing unit of claim 5, wherein the cooling liquid supply line includes a supply pump, wherein the supply pump is controlled at a variable rate by the pressure sensor to increase or decrease a rate of condensation of two phase liquid coolant in vapor phase, to maintain the pressure within the vapor container to the predetermined range.

7. The condensing unit of claim 1, wherein the liquid container further comprises a direct return line operable without a pump to return two phase liquid coolant in liquid phase to a server region of the electronic rack caused by the pressure built up within the vapor container.

8. The condensing unit of claim 1, wherein the liquid container further comprises a liquid outlet line and a return pump, wherein the return pump is activatable by the pressure sensor to return two phase liquid coolant in liquid phase to a server region of the electronic rack or to a facility liquid coolant source.

9. The condensing unit of claim 1, wherein the vapor container comprises:
a vapor release port situated at a section of the vapor inlet; and
a release valve coupled to the vapor release port, wherein the release valve is activatable by the pressure sensor to release vapor from the vapor container via the vapor inlet.

10. The condensing unit of claim 1, wherein the vapor container and liquid container are separated by an air lock mechanism to lock in an air volume within the vapor container.

11. The condensing unit of claim 1, wherein the air sealing mechanism allows liquid to flow between the vapor container and the liquid container but prevents vapor from flowing from the vapor container to the liquid container.

12. The condensing unit of claim 1, further comprising an external chassis containing the vapor container and the liquid container.

13. An electronic rack, comprising:
a server region having a plurality of server slots to receive a plurality of servers, wherein each of the servers is at least partially submerged within two phase liquid coolant within an immersion section, wherein, when the servers operate, the servers generate heat that is transferred to the two phase liquid coolant thereby causing at least some of the two phase liquid coolant to turn into a vapor; and
a condensing unit coupled to the server region, the condensing unit comprising:
a vapor container housing condensing coils, the vapor container being pressurized to increase a rate of condensation of two phase coolant in vapor phase,
a vapor inlet situated at the vapor container for two phase liquid coolant in vapor phase to enter the vapor container,
a liquid container situated underneath the vapor container and attachable to the vapor container to receive two phase liquid coolant in liquid phase from the vapor container,
a liquid level sensor situated within the liquid container to measure a liquid level for liquid contained in the liquid container, and
a pressure sensor situated at the vapor container to measure a pressure within the vapor container, wherein the pressure sensor is used to regulate a pressure in the condensing unit within a predetermined range thereby maintaining a steady rate of condensation by the condensing coils and an outflow rate of two phase liquid coolant from the liquid container.

14. The electronic rack of claim 13, wherein the vapor container comprises:
a release port situated near a top portion of the vapor container; and
a release valve coupled to the release port, wherein the release valve is activatable by the pressure sensor to release air and/or vapor from the vapor container.

15. The electronic rack of claim 14, wherein the release valve is a three way valve having a first port to release air to a surrounding environment and a second port coupled to another condensing unit.

16. The electronic rack of claim 13, wherein the vapor container further comprise:
a cooling liquid supply line; and
a cooling liquid return line, wherein the cooling liquid supply line and cooling liquid return line are coupled to the condensing coils to supply cooling liquid from, and return cooling liquid to a facility source.

17. The electronic rack of claim 16, wherein the cooling liquid supply line includes a supply pump, wherein the supply pump is controlled at a variable rate by the pressure sensor to increase or decrease a rate of condensation of two phase liquid coolant in vapor phase, to maintain the pressure within the vapor container to the predetermined range.

18. The electronic rack of claim 13, wherein the liquid container further comprises a direct return line operable without a pump to return two phase liquid coolant in liquid phase to a server region of the electronic rack caused by the pressure built up within the vapor container.

19. The electronic rack of claim 13, wherein the liquid container further comprises a liquid outlet line and a return pump, wherein the return pump is activatable by the pressure sensor to return two phase liquid coolant in liquid phase to a server region of the electronic rack or to a facility liquid coolant source.

20. A data center system, comprising:
a plurality of electronic racks, each of the electronic racks including:
a server region having a plurality of server slots to receive a plurality of servers, wherein each of the servers is at least partially submerged within two phase liquid coolant within an immersion section, wherein, when the servers operate, the servers generate heat that is transferred to the two phase liquid coolant thereby causing at least some of the two phase liquid coolant to turn into a vapor; and
a condensing unit coupled to the server region, the condensing unit comprising:
a vapor container housing condensing coils, the vapor container being pressurized to increase a rate of condensation of two phase coolant in vapor phase,
a vapor inlet situated at the vapor container for two phase liquid coolant in vapor phase to enter the vapor container,
a liquid container situated underneath the vapor container and attachable to the vapor container to receive two phase liquid coolant in liquid phase from the vapor container,
a liquid level sensor situated within the liquid container to measure a liquid level for liquid contained in the liquid container, and
a pressure sensor situated at the vapor container to measure a pressure within the vapor container, wherein the pressure sensor is used to regulate a pressure in the condensing unit within a predetermined range thereby maintaining a steady rate of condensation by the condensing coils and an outflow rate of two phase liquid coolant from the liquid container.
